(19) United States
(12) Patent Application Publication
(10) Pub. No.: US 2023/0124695 A1
(43) Pub. Date: Apr. 20, 2023

(54) INCREASING TRANSISTOR GAIN USING METAMATERIAL ELECTRODES

(71) Applicant: BOARD OF TRUSTEES OF THE UNIVERSITY OF ARKANSAS, Little Rock, AR (US)

(72) Inventors: Amirreza Ghadimi Avval, Fayetteville, AR (US); Samir El-Ghazaly, Fayetteville, AR (US)

(73) Assignee: BOARD OF TRUSTEES OF THE UNIVERSITY OF ARKANSAS, Little Rock, AR (US)

(21) Appl. No.: 17/910,782

(22) PCT Filed: Mar. 9, 2021
(86) PCT No.: PCT/US2021/021509

§ 371 Date: Sep. 9, 2022

Related U.S. Application Data
(60) Provisional application No. 62/986,906, filed on Mar. 9, 2020.

(51) Int. Cl. H01L 21/20; H01L 29/20; H01L 29/205; H01L 29/423; H01L 29/66

(52) U.S. Cl. CPC H01L 21/2011; H01L 29/2003; H01L 29/205; H01L 29/42316; H01L 29/66462

(57) ABSTRACT

A transistor using patterned metamaterial electrode manipulating electromagnetic waves to achieve matched phase velocity on the input and output ports. A design method is taught wherein the layout of the electrodes can be designed to compensate for the phase-velocity mismatch induced by the transistor's intrinsic properties.

### CROSS-REFERENCE TO RELATED APPLICATIONS

This application is a U.S. 371 National Phase of PCT/US/2021/021509 filed on Mar. 9, 2021, which claims priority to and is a continuation-in-part of U.S. Patent Application Ser. No. 62/986,906, filed on Mar. 9, 2020 entitled Increasing Transistor Gain Using Metamaterial Electrodes which is hereby incorporated by reference in its entirety.

### STATEMENT REGARDING FEDERALLY SPONSORED RESEARCH OR DEVELOPMENT

This invention was made with government support by the National Science Foundation with cooperative agreement US/NSF/1745143/EAGER: SAPPHIRE BASED INTEGRATED MICROWAVE PHOTONICS (0402 01998-21-0000). The government has certain rights in the invention.

### RESERVATION OF RIGHTS

A portion of the disclosure of this patent document contains material which is subject to intellectual property rights such as but not limited to copyright, trademark, and/or trade dress protection. The owner has no objection to the facsimile reproduction by anyone of the patent document or the patent disclosure as it appears in the Patent and Trademark Office patent files or records but otherwise reserves all rights whatsoever.

### BACKGROUND OF THE INVENTION

### 1. Field of the Invention

The present invention relates to improvements in transistors and electronics. More particularly, the invention relates to improvements in the electrodes to phase match the input and output of the transistor or electronic device to increase gain or other performance characteristics of the device.

### 2. Description of the Known Art

As will be appreciated by those skilled in the art, transistors are known in various forms. Patents and Applications disclosing information relevant to transistors include: U.S. Pat. No. 10,748,996, issued to Mokhti, et al. on Aug. 18, 2020 entitled High power transistor with interior-fed gate fingers; U.S. Pat. No. 9,570,565, issued to Prechtl on Feb. 14, 2017, entitled Field effect power transistor metalization having a comb structure with contact fingers; U.S. Pat. No. 9,543,403, issued to Ding, et al. on Jan. 10, 2017 entitled Bipolar junction transistor with multiple emitter fingers; U.S. Pat. No. 9,070,761, issued to Johnson on Jun. 30, 2015 entitled Field effect transistor (FET) having fingers with rippled edges; U.S. Pat. No. 8,796,697, issued to Kunii, et al. on Aug. 5, 2014 entitled Semiconductor device including transistor chips having oblique gate electrode fingers; U.S. Pat. No. 8,174,054, issued to Miller on May 8, 2012 entitled Field effect transistor with interdigitated fingers and method of manufacturing thereof; U.S. Pat. No. 7,498,872, issued to Nishimoto, et al. on Mar. 3, 2009 entitled Transistor devices configured to operate above a first cutoff frequency; U.S. Pat. No. 7,095,080, issued to Johansson, et al. on Aug. 22, 2006 entitled RF power LDMOS transistor with multiple gate fingers; and U.S. Pat. No. 5,057,883, issued to Noda on Oct. 15, 1991 entiteld Permeable base transistor with gate fingers. These patents are hereby expressly incorporated by reference in its entirety.

Additional materials for consideration include:

A. G. Avval, E. Larique, and S. M. El-Ghazaly, “Heterojunction field effect transistors,” Reference Module in Materials Science and Materials Engineering, Elsevier, 2018.

S. El-Ghazaly and T. Itoh, “Inverted-gate field-effect transistors: novel high-frequency structures,” in IEEE Transactions on Electron Devices, vol. 35, no. 7, pp. 810-817, July 1988.

S. M. El-Ghazaly and T. Itoh, “Traveling-wave inverted-gate field-effect transistors: concept, analysis, and potential,” in IEEE Transactions on Microwave Theory and Techniques, vol. 37, no. 6, pp. 1027-1032, June 1989.

S. M. Hammadi, S. M. El-Ghazaly, “Air-bridged gate MESFET: a new structure to reduce wave propagation effects in high-frequency transistors”, Microwave Theory and Techniques IEEE Transactions on, vol. 47, no. 6, pp. 890-899, 1999.

W. Heinrich, “Wave Propagation Along GaAs-FET Electrodes”, Journal of Electromagnetic Waves and Applications, vol. 5, pp. 403, 1991.

Finally, a basic understanding of transistors and the currently accepted design parameters and limitation should also be considered. A transistor is a device, composed of semiconductor materials, which is used to switch or amplify electronic signals. Transistors are connected to external devices and circuits using three terminals. The general function of these devices is that the current through one terminal pair is controlled by the voltage or current that is applied to the other pair. The transistor performs an amplification functionality when the output power is higher than the input power. Historically, transistors were only packaged individually for different applications, but are now configured mostly as integrated circuits. Cheaper and smaller computers, radios, and smartphones owe their emergence to the technological advancements of transistors. Vacuum tubes were the forerunner of transistors, which were generally bigger and required more power to operate. Silicon, germanium, gallium arsenide, silicon carbide, and gallium nitride are some of the semiconductor materials used in transistor structures. Current transistors can be classified into two main categories, field effect transistors (FETs) and bipolar junction transistors (BJTs). For FETs, only one type of charge carrier is involved in device operations, whereas BJTs have both types of charge carriers.

An important property associated with transistors is the gain of the device which is defined as controlling a very large signal by applying a much smaller signal. In other words, the transistor acts as an amplifier, when a weak input signal is transformed into a stronger voltage or current at the output port. When the transistor is used as a switch, it only turns the current on and off. The general operation of various transistor types are almost identical. Emitter, collector, and base are the names of the terminals in a bipolar transistor where a small current is “typically” applied to the base-emitter terminal pair. This current controls a large current at the collector-emitter junction. Similarly, for a field effect transistor, the terminal labels are source, drain, and gate where a current between drain and source is controlled by applying a voltage at the gate terminal. That is to say, the flow of current is controlled by an electric field.

In field effect transistors, the current may be carried by majority or minority carriers. The active channel is one of the semiconductor layers in the structure of these devices, through which the flow of charge carriers happens from source electrode to the drain electrode. This layer has a conductivity which is controlled by the potential applied between the gate and source electrodes. The conductors for the drain and source electrodes are grown on the semiconductor layers as ohmic contacts. The gate terminal controls the opening and closing modes of the channel layer and the channel conductivity is modulated by this terminal. This is performed by applying a voltage to the gate which determines the electron, or holes, flow between source and drain terminals by creating a depletion region.

As already stated, the ability of an amplifier (often realized as a two-port circuit) to increase the signal power or amplitude at the output port is considered as the gain of that device. The term normally indicates the ratio of a parameter value at the output port to the value of the same parameter at the input port. This parameter may be the power, voltage, or current at the device ports. The transistor is called an active device when its gain is greater than one. Typically, for radio frequency devices, the power or current gain of the transistor is considered as one of the most critical characteristics which determines the most suitable applications that the mentioned device fits into. Moreover, the frequency at which the device operates is one of the factors that may cause the device gain to change.

High-power and high-frequency transistors are the devices that embody the future of wireless communication systems in achieving higher data rates. Examples of these systems are 5G technology, satellite communications, and ultra-wideband systems, all of which owe their advancements to the device properties of MESFETs (metal-semiconductor field effect transistor), HEMTs (high electron mobility transistor), Heterostructure Bipolar junction Transistors (HBTs), and related structures. MESFETs are normally fabricated using compound semiconductor materials such as gallium arsenide and are typically faster than silicon based FETs. The frequency handling capabilities of the MESFETs are improved when the gate length is short enough. HEMT devices are generally fabricated using two materials with different bandgaps, such as gallium nitride and aluminum gallium nitride. The operating frequency of HEMTs are generally extended to millimeter wave range. High saturation velocity, high electron mobility, high sheet carrier density, and high breakdown voltage are some of the characteristics of GaN HEMTs that meet the requirements of building high-power amplifiers (HPAs) capable of working at high operating frequencies and high temperatures. This subject matter has attracted the attention of many research scientists and engineers to enhance the device performance for various applications. Moreover, developing accurate modeling techniques for these devices is demanded in order to have a simulation tool which predicts the device behavior and may be used at the design stage as well.

From these prior references it may be seen that the prior art is very limited in its teaching and utilization, and an improved transistor and method of both design and construction is needed to overcome these limitations.

### SUMMARY OF THE INVENTION

The present invention is directed to an improved transistor using metamaterials at the connections to ensure the matching of phase velocities at the input and output ports. For the transistors operating at high-frequency bands, the concept of wave propagation or distributed effects are dominant in the device operations. Dissimilarities in design parameters between the input and output ports of the transistor induce a phase velocity mismatch on the input and output electrodes of the device, which reduces the gain and output power of the transistor. The mentioned limitations prevent fabrication of wider devices. Thus, utilizing multiple fingers, with added discontinuities and interconnects, for achieving higher gain values is inevitable. A novel design technique is proposed here, where the electrodes of the transistor are rearranged using metamaterials to ensure the matching of phase velocities at the input and output ports. For a device width of 300 μm working at 60 GHz, the current gain of the proposed transistor is compared with the typical model and a 130% increase is observed. Thus, at high operating frequency ranges and for wider devices, the transistors with rearranged electrode configuration yield 2-3 times higher gains compared to normal devices.

The main advantage of this idea is that its fabrication procedure for this technique is very similar to normal devices and there is no need to change the pertaining machinery. Additionally, 2-3 times higher gains are obtained using a single transistor device fabricated based on this method.

These and other objects and advantages of the present invention, along with features of novelty appurtenant thereto, will appear or become apparent by reviewing the following detailed description of the invention.

### BRIEF DESCRIPTION OF THE SEVERAL VIEWS OF THE DRAWINGS

In the following drawings, which form a part of the specification and which are to be construed in conjunction therewith, and in which like reference numerals have been employed throughout wherever possible to indicate like parts in the various views:

FIG. 1 is a cross-section of the 0.1-μm AlGaN/GaN HEMT device on sapphire substrate operating at GHz frequency band.

FIG. 2 is an equivalent circuit model of the HEMT used in the distributed modeling approach.

FIG. 3 shows the gate and drain currents along the device width for five different frequencies (travelling wave signals).

FIG. 4 shows the gate and drain currents along the device width for five different frequencies (standing wave signals).

FIG. 5 shows the output power for 10-250 GHz frequency band.

FIG. 6 shows the proposed configuration for the drain electrode for compensating the phase velocity mismatch.

### DETAILED DESCRIPTION OF THE INVENTION

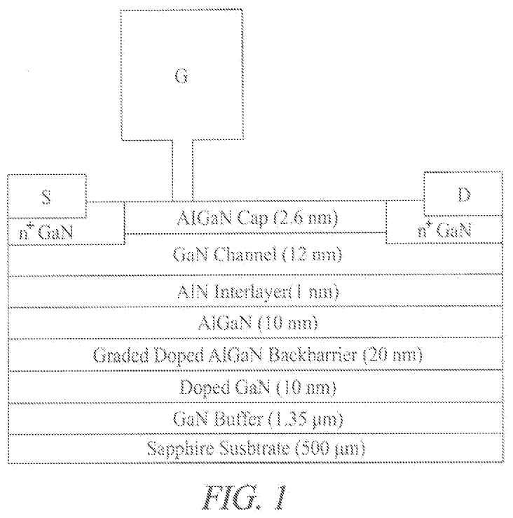

As shown in FIGS. 1 through 6 of the drawings, one exemplary embodiment of the present invention is generally shown as metamaterial electrode transistor.

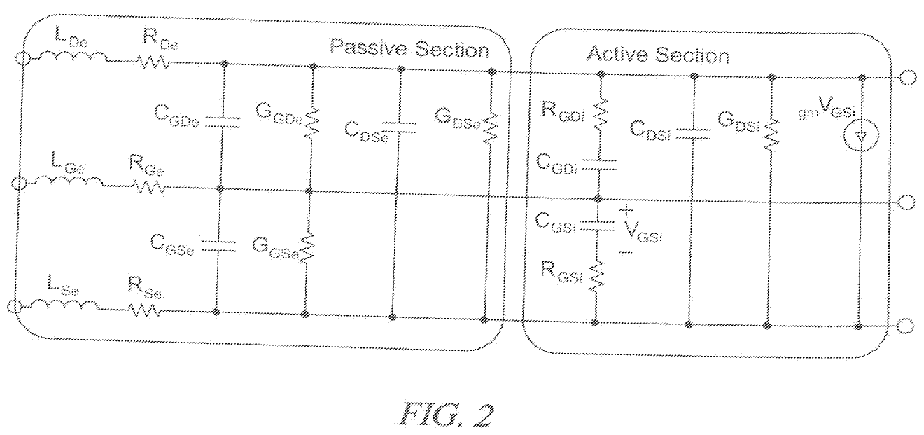

A first embodiment shown in FIGS. 1 and 2 show a cross-section of the 0.1-μm AlGaN/GaN HEMT device on sapphire substrate operating at GHz frequency band. Examples of other electronic devices or components on which this may be utilized include single or multiple diodes, transistors, or combinations thereof. The invention may be utilized on single or multiple fingers of the devices themselves or in the networks feeding the devices.

Two of the most vital transistor properties for today's applications are the gain and output power that are related directly to the width of the device, especially in FET structures. The device width signifies the direction along the device electrodes, perpendicular to the flow of charges. This dimension is limited by the concept of distributed or wave propagation effects, where the device width is typically kept much smaller than the wavelength of the guided wave. This limitation is more notable when the operating frequency of the device is high and the input reactance (gate to source) and output reactance (drain to source) are significantly different in a common source configuration. The electrodes of such devices will act as transmission lines due to their comparable width to the wavelength. Consequently, the phase velocity at the input, gate electrode, and output, drain electrode, will be different. The phase velocity mismatch will cause a reduction in the amount of gain and output power of the transistor. In order to prevent this from happening, the fabricated device width is limited to less than one-tenth of the propagating wavelength, which makes the effects of the velocity mismatch ignorable. However, as a result, multiple transistor fingers are incorporated in order to obtain more output power. This approach necessitates using numerous interconnects which, in turn, adds more parasitic elements. The added parasitic elements effectively limit the device operating frequency and complicate the matching circuits.

FIG. 1 shows the cross-section of a 0.1-μm gallium nitride high electron mobility transistor with an operating frequency at the millimeter wave band. The different semiconductor layer thicknesses and doping profiles along with the substrate are presented in this figure. The term 0.1-μm indicates the gate length of the transistor. For analyzing this device, an in-house already-developed distributed modeling technique is utilized. This technique is capable of yielding accurate results at very high frequencies. Initially, one of the limitations of HEMT devices was the attenuation of the signal along the input gate electrode due to the presence of a parasitic resistance. This limitation is addressed with increasing the cross-sectional area of the gate conductor without changing the stem length, which is the reason for realizing it in either T-shape or mushroom-shape configurations. The cross-sectional dimensions for the electrode layouts are as follows:

Drain and source conductors: 6 μm×0.12 μm

Gate stem: 0.1 μm×0.22 μm

Gate top: 0.45 μm×0.53 μm

Gate-source spacing: 0.3 μm

Gate-drain spacing: 1.6 μm

The 19-element equivalent circuit model for the GaN HEMT device is depicted in FIG. 2. The bias independent extrinsic elements form the passive section of the device, whereas the bias dependent intrinsic components represent the active part. There are specific physical descriptions associated with the elements presented at this model. R_{GSi} represents the channel resistance and R_{GDi} is a complement to that element in order to have a symmetry in the model. C_{GSi} and C_{GDi} demonstrate the charge modulation for the gate electrode when V_{GS} and V_{DS} change, respectively. Gate electrode contact is associated with a Schottky barrier and R_{Ge} shows the resistance to the current flow along the metal strip. Furthermore, R_{De} and Rₛₑ indicate the resistance of the drain and source ohmic contacts and the access region. The extraction procedure for the transmission line parameters is based on the physical layout of the device and any arbitrary shape in the cross-section may be evaluated based on it.

According to the device structure in FIG. 1, the separation between the input and output conductors is 1.6 μm, the thickness of the active layer is roughly 0.1 μm, and the operating frequency for this device is in the range of millimeter-wave. These are the typical features of most high frequency GaN HEMTs. The capacitance of the transmission line section is obtained by solving a three dimensional Laplace equation for the conductors using COMSOL Multiphysics. The materials used for the electrodes are gold and titanium. The magnetic wall boundary conditions are defined based on the accumulation of most of the energy in the area between the gate and drain electrodes.

One of the other outcomes of the small transistor cross-sectional dimensions, with respect to the wavelength of the propagating wave, is that the AlN, AlGaN, GaN, and substrate layers under the electrodes do not have an effect on the solution of the magnetic field. Hence, the electrodes are assumed to be in free space where the relative permittivity of the medium is one. The extraction process starts with solving the 3D Laplace equation for the new structure and finding the self-capacitance on each conductor, where one electrode is excited by a voltage and the charge is then observed on the same electrode. The inductance of the line is derived by using equation (1), where c is the speed of light, C is the per unit width self-capacitance on each conductor, and L denotes the per unit width inductance of the line.

c=1/\sqrt{LC} (1)

The presence of conductance parameter is tied to the conductivity of all the layers under the electrodes since the conducting path is through the dielectric or semiconductor materials. This parameter is derived by using equation (2). Based on the doping types and the fact that the mobility of electrons is larger than that of holes, we assume that the conduction in the layers is entirely due to electrons. Hence, n is the carrier concentration, u. denotes the electron mobility, q is the electron charge, and σ shows the conductivity. Similar to obtaining the capacitance, the 3D structure of the device is arranged, without the need to define magnetic walls as the boundary conditions. The mutual conductance is obtained by applying a voltage to one electrode and observing the current on the other two conductors

σ=qμn (2)

In order to find the resistance or conductor loss of the line, Wheeler's Incremental Inductance rule is used. Since gold and titanium, as the materials used for fabricating the conductors, are lossy metals, the magnetic field penetrates the electrodes, which leads to generation of an internal inductance. To estimate the value of it, first the external inductance of the line is calculated as explained before. Then, all the surfaces of the conductors are recessed by a small amount equal to half the skin depth and the external inductance is calculated for the new case as well. The difference between the two calculated values indicates the internal inductance as explained in equation (3), where δ denotes the skin depth, Lᵢₙₜ is the internal inductance, and Lₑₓₜ signifies the external inductance. Moreover, the current flow within the electrodes causes a surface impedance for which the real and imaginary parts are equal. This relates the resistance of the line to the internal inductance as explained in equation (4), where ω indicates the angular operating frequency.

Lᵢₙₜ=Lₑₓₜ(x)−Lₑₓₜ(x−δ/2) (3)

R=ωLᵢₙₜ (4)

Finally, the proposed device is simulated in a common-source configuration using SILVACO. The Y-parameters of the two port equivalent model is obtained over a defined frequency range and the intrinsic parameter values of the device are calculated. Other than the 9 defined elements for the intrinsic part of the model, there are two resistance elements associated with the gate-drain and gate-source current leakage. For the state-of-the-art GaN HEMTs, these elements possess negligibly small values and are not needed to be considered in the model. Furthermore, since the gate length of the device is very small and the operating frequency is high, the proposed relations do not yield an accurate value for gate-drain resistance and this parameter must be optimized to fit the obtained results. The per unit width parameter values for the intrinsic and extrinsic elements are summarized in Table I. An unconditionally stable implicit finite difference numerical method is used for the analysis of the device in different frequency bands and the results show good agreements with the obtained results from fabrication.

TABLE 1
Extracted parameter values

| Extrinsic Parameters | | Intrinsic Parameters |
|---|---|---|
| L_{Se} = 2.40 nH/cm | C_{GDe} = 314 fF/cm | C_{GSi} = 8.38 pF/cm |
| L_{Ge} = 2.58 nH/cm | C_{GSe} = 898 fF/cm | R_{GSi} = 5.56 mΩ · cm |
| L_{De} = 4.48 nH/cm | C_{DSe} = 572 fF/cm | C_{GDi} = 332 fF/cm |
| R_{Se} = 60 Ω/cm | G_{GDe} = 0.01 mS/cm | R_{GDi} = 238 mΩ · cm |
| R_{Ge} = 165 Ω/cm | G_{GSe} = 0.02 mS/cm | C_{DSi} = 21.5 pF/cm |
| R_{De} = 60 Ω/cm | G_{DSe} = 0.01 mS/cm | G_{DSi} = 1.70 S/cm |
| | | gₘ = 6.10 S/cm |

For an operating frequency of f=60 GHz, the propagating wavelength in free space is equal to 2=5000 μm, that is the speed of light divided by the frequency. However, the speed of the propagating wave in the device is roughly one-third of this value which makes the guided wavelength be equal to λₛ=1667 μs. If the device width is assumed to be 300 μm, this dimension will be comparable to the wavelength of device since it is not smaller than one-tenth of it. Consequently, the wave propagation effects will be pronounced and it is predicted that there will be a phase velocity mismatch in this device. In order to have a point of comparison, the current gain of this device is calculated using equation (5). The value for the current gain at 60 GHz is equal to 3.85 dB. According to the obtained parameter values in Table 1, the phase velocity at the input and output ports of the device must be calculated and two operating modes, namely even and odd, are considered for this purpose.

G_{c}=20×log(Iₒᵤₜ/in) (5)

For the even or gate mode, the source and drain lines are excited with a negative voltage and a positive voltage is applied to the gate conductor. The per unit width extrinsic capacitance on the gate line is calculated based on the proposed method, which is equal to C_{g}=1.21×10⁻¹² F/cm. The intrinsic capacitance associated with this conductor is also added to this value and the resulting Cₑᵥₑₙ=1.04×10⁻¹¹ F/cm is obtained. Using the L_{g} value from Table 1, the phase velocity on the gate line becomes vₚ=6.10×10⁹ cm/s, which is calculated using equation (6). This equation is similar to equation (1) and both the capacitance and inductance are calculated for one unit width of the device.

vₚ=1/\sqrt{LC} (6)

To excite the conductors for the odd or drain mode, a positive voltage is applied to the drain electrode and the source is connected to a negative voltage. The capacitance on the drain is obtained (C_{d}=8.26×10⁻¹³ F/cm) and added to the capacitance value for the intrinsic part of the device related to the drain electrode. The total value equals to C_{odd}=2.95×10⁻¹² F/cm. Using the per unit width L_{d} value from Table 1 and equation (6), the resulting phase velocity on the drain electrode becomes v_{d}=8.70×10⁹ cm/s. Clearly, there is velocity mismatch between the input (gate) and output (drain) conductors of about 43%, which is a reason for lower gain and output power of the device.

The main contributions of this work can be summarized as follows: (1) To improve the performance of a high-frequency transistor (i.e., increasing output power, gain, cut-off frequency, etc.), the transistor electrodes are designed to provide matched phase velocities on the input and output ports. (2) This phase velocity matching can be accomplished by properly designing the electrodes, with minimal limitations due to the transistor's cross-sectional design. In other words, this work proposes that the layout of the electrodes can be designed to compensate for the phase-velocity mismatch induced by the transistor's intrinsic properties. (3) This work provides an example for realizing this phase-velocity matching using metamaterial concepts, based on which a new set of electrodes are designed. (4) Transistors designed based on this concept may be realized in wider fingers (i.e., longer than one tenth of the wavelength) due to the matched phase velocity. Hence, a much smaller number of wider electrodes can be used to provide certain power and gain. Consequently, the losses, discontinuities inside the device, and possibly the transistor's footprint can be reduced. (5) Typically, metamaterials are arranged in some defined repeating patterns and have properties that the natural materials does not possess, making them capable of manipulating electromagnetic waves.

In order to match the phase velocity of the output port to the input port, the drain electrode is designed using metamaterial concepts and the above-mentioned procedure is applied to the new device to find the phase velocity on the drain conductor. The new drain capacitance equals C_{d}=1.39×10⁻¹² F/cm and when added to the intrinsic capacitance, the resulting value becomes Cₑᵥₑₙ=3.51×10⁻¹² F/cm. Moreover, the effect of the new design on the inductance is also considered and the drain inductance is obtained (L_{d}=7.35×10⁻⁹ H/cm). Using the new values obtained for the capacitance and inductance, the phase velocity on the drain conductor becomes v_{d}=6.22×10⁹ cm/s, which is almost identical to the phase velocity on the gate electrode. The current gain of the new transistor with the same width (300 μm) at an operating frequency of 60 GHz is calculated which equals to 8.86 dB. This figure shows a 130% increase in the amount of gain compared to the previous case.

The modeling procedure utilized for the simulation of the transistor has already been verified with the results obtained from a fabricated GaN HEMT device. This method is comprised of three different simulation tools, namely COMSOL Multiphysics, SILVACO, and a finite-difference time-domain analysis. Correspondingly, the redesigned electrode configurations and the new transistor model are all simulated and compared using this procedure.

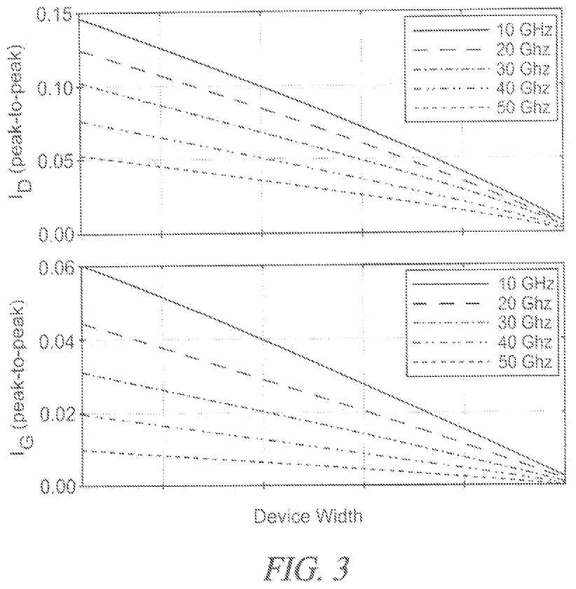

FIG. 3 shows the gate and drain currents along the device width for five different frequencies (travelling wave signals). For high-frequency devices, in general, higher gain is associated with the added distributed transconductance effect which is a direct outcome of widening a device. However, as mentioned before, due to the phase velocity mismatch on the input and output ports beyond a certain frequency point, the performance improvements do not have a linear relation with the device width. In order to elaborate on how the electromagnetic wave propagation phenomenon affects the device output, the current is observed over the device width (75 μm) according to the developed distributed modeling approach. FIG. 3 shows the peak-to-peak value of the gate and drain currents for five different operating frequencies. Based on the fact that for the observed operating frequencies, the device is electrically small compared to the wavelength, a pure travelling-wave pattern is observed over the device. With this said, the phase mismatch limitations and the wave propagation effects are not yet observed.

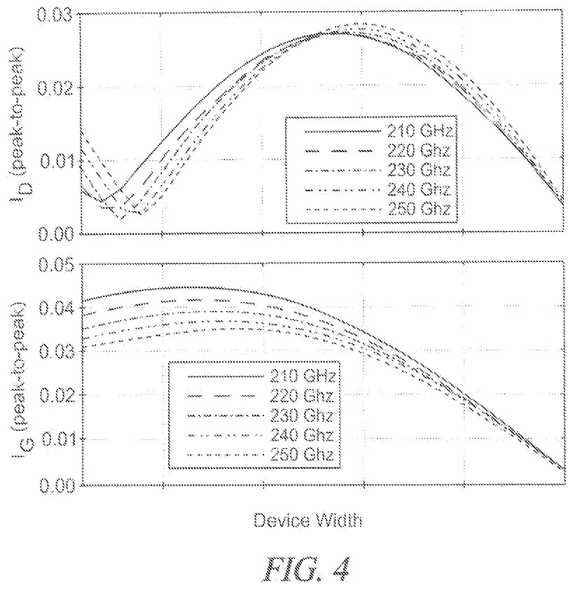

FIG. 4 shows the gate and drain currents along the device width for five different frequencies (standing wave signals). For higher operating frequencies, the travelling-wave behavior of the waves on the input and output electrodes may not be maintained. Due to the presence of a velocity mismatch phenomenon, the signals on the gate and drain electrodes are a combination of two or more waves propagating at the same operating frequency. This type of wave is called a standing wave, which is generated by a continuous interaction between the input and output signals along the device width. Hence, distortions are observed in the propagating signal and the desired device gain is no longer obtained. This phenomenon is depicted in FIG. 4, where the operating frequencies are high enough compared to the device width. The phase mismatch caused by the wave propagation effects are observable and the current signals partially demonstrate a standing-wave behavior.

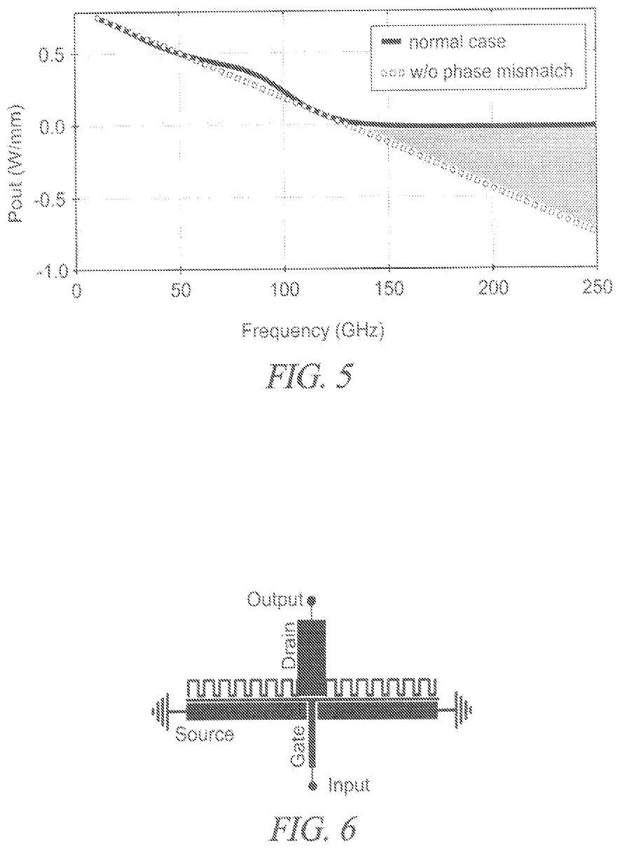

FIG. 5 shows the Output power for 10-250 GHz frequency band. Another indication of observable phase mismatch is the nonlinear relation between the output power and the operating frequency. FIG. 5 shows the output power for the 75 μm HEMT device over a broad operating frequency band. It is clearly demonstrated how the creation of partial standing waves imposes a nonlinear behavior at the output. It is worth noting that for the normal case, the dispersion of the transconductance is not considered in the model as our main goal is to show the effects of the mismatch in the phase velocity of the input and output conductors. Obviously, the wave propagation effects are observable above the operating frequency of 150 GHz. By removing these effects, the device performance, which is demonstrated by the blue line, will be improved to be in the shaded yellow section and the maximum improvement (fully linear performance) is depicted by the dashed red line.

The main parameter that imposes this limitation on the high-frequency operability of the device is the intrinsic gate-source capacitance. It suppresses the velocity of the signal on the gate electrode which results in a mismatch between the drain and gate electrodes. Hence, the solution for matching the velocity of the signals on the input and output ports lies in adjusting the extrinsic parameters on the drain side to reduce the signal velocity. In other words, the optimized electrode design will be a compensation for the imposed limitations by the intrinsic device parameters.

FIG. 6 shows proposed configuration for the drain electrode for compensating the phase velocity mismatch. The layout arrangement in FIG. 6 suggests a defined repeating pattern for the drain electrode to compensate for the mismatch between the input and output electrodes. This will ensure that the electromagnetic signals inside the device are manipulated in a way that wave propagation effects are no longer observable. The air gaps in the structure of the drain electrode impose some extra capacitance to the extrinsic side of the device. Adjusting the dimensions for these gaps will ensure that the overall drain-source capacitance will increase to a point that the phase velocities on the gate and drain line becomes equal and, hence, the mismatch effects are compensated.

m the foregoing, it will be seen that this invention well adapted to obtain all the ends and objects herein set forth, together with other advantages which are inherent to the structure. It will also be understood that certain features and subcombinations are of utility and may be employed without reference to other features and subcombinations. This is contemplated by and is within the scope of the claims. Many possible embodiments may be made of the invention without departing from the scope thereof. Therefore, it is to be understood that all matter herein set forth or shown in the accompanying drawings is to be interpreted as illustrative and not in a limiting sense. When interpreting the claims of this application, method claims may be recognized by the explicit use of the word ‘method’ in the preamble of the claims and the use of the ‘ing’ tense of the active word. Method claims should not be interpreted to have particular steps in a particular order unless the claim element specifically refers to a previous element, a previous action, or the result of a previous action. Apparatus claims may be recognized by the use of the word ‘apparatus’ in the preamble of the claim and should not be interpreted to have ‘means plus function language’ unless the word ‘means’ is specifically used in the claim element. The words ‘defining,’ having,' or ‘including’ should be interpreted as open ended claim language that allows additional elements or structures. Finally, where the claims recite “a” or “a first” element of the equivalent thereof, such claims should be understood to include incorporation of one or more such elements, neither requiring nor excluding two or more such elements.

1. A transistor with an input port and an output port, the transistor having matched phase velocity on the input and output ports.

2. The transistor of claim 1, further comprising:
the transistor operating with a wavelength;
the transistor including fingers having a finger width greater than one tenth of the wavelength.

3. A transistor electrode compensating for a phase-velocity mismatch induced by the transistor's intrinsic properties.

4. (canceled)

5. An electronic device with modified electrodes that have equal electromagnetic-wave phase velocity.

6. An electronic device for receiving an input electromagnetic wave on an input line including an input phase velocity, comprising:
a first wave shifting electrode to increase the input phase velocity to a device phase velocity.

7. The electronic device of claim 6 connected to an output line with a desired output phase velocity, the electronic device comprising:
a second wave shifting electrode to decrease the device phase velocity to the desired output phase velocity.

8. An electronic device with a device phase velocity connected to an output line with a desired output phase velocity, the electronic device comprising:
a wave shifting electrode to decrease the device phase velocity to the desired output phase velocity.

9. An electronic device with a device phase velocity for receiving an input electromagnetic wave with an input phase velocity on an input line, the electronic device comprising:
at least one multiple finger connection, the at least one finger connection using wave shifting electrodes to increase the input phase velocity on the input line to the device phase velocity.

10. An electronic device with a device phase velocity for sending an output electromagnetic wave with a desired output phase velocity on an output line, the electronic device comprising:
an output multiple finger connection, the at least one finger connection using wave shifting electrodes to decrease the device phase velocity to the desired output phase velocity.

11. An electronic device with a device phase velocity for receiving an input electromagnetic wave with an input phase velocity on an input line, the electronic device comprising:
an input multiple finger connection, the input multiple finger connection using input wave shifting electrodes to increase the input phase velocity on the input line to the device phase velocity; and
an output multiple finger connection, the output finger connection using output wave shifting electrodes to decrease the device phase velocity to the desired output phase velocity.
